(19) United States
(12) Patent Application Publication
(10) Pub. No.: US 2021/0242363 A1
(43) Pub. Date: Aug. 5, 2021

(54) SEMICONDUCTOR ELEMENT, SEMICONDUCTOR DEVICE AND SEMICONDUCTOR SYSTEM

(71) Applicant: FLOSFIA INC., Kyoto (JP)

(72) Inventors: Mitsuru OKIGAWA, Kyoto (JP); Manabu KIGUCHI, Kyoto (JP); Koji AMAZUTSUMI, Kyoto (JP)

(21) Appl. No.: 17/163,826

(22) Filed: Feb. 1, 2021

(30) Foreign Application Priority Data
Jan. 30, 2020 (JP) 2020-013611
Jan. 30, 2020 (JP) 2020-013612
Jan. 30, 2020 (JP) 2020-013613
Mar. 19, 2020 (JP) 2020-048704
Mar. 19, 2020 (JP) 2020-048705
Mar. 19, 2020 (JP) 2020-048706
Mar. 19, 2020 (JP) 2020-048707

(51) Int. Cl. H01L 31/173; H01L 31/032; H01L 31/113

(52) U.S. Cl. CPC H01L 31/173; H01L 31/1136; H01L 31/032

(57) ABSTRACT

A semiconductor element and/or semiconductor device having enhanced semiconductor characteristics useful as power devices are provided. A semiconductor element, including: a first electrode; a second electrode; an n−-type semiconductor layer; and a low electrically conductive layer, the low electrically conductive layer that is arranged between the first electrode and the n−-type semiconductor layer, a first barrier height of the first electrode is larger than a second barrier height of the second electrode, a first electrical resistivity of the low electrically conductive layer is equal to or more than 1000 times as large as a second electrical resistivity of the n−-type semiconductor layer, and the semiconductor element that is configured to be able to irradiate light from an outside to at least a part of the low electrically conductive layer.

### TECHNICAL FIELD

The present invention relates to a semiconductor element and/or a semiconductor device useful as power devices, and a semiconductor system including the semiconductor element and/or the semiconductor device.

### BACKGROUND ART

As a switching device of the next generation achieving high withstand voltage, low losses, and high temperature resistance, semiconductor devices using gallium oxide (Ga₂O₃) with a large band gap attract attention and are expected to be applied to power semiconductor devices including an inverter. Also, gallium oxide is expected to be applied to a light emitting and receiving element such as a light emitting diode (LED) and a sensor, since gallium oxide has a wide band gap. According to Non-Patent Literature 1, such gallium oxide has a band gap that may be controlled by forming mixed crystal with indium or aluminum singly or in combination and such a mixed crystal is extremely attractive materials as InAlGaO-based semiconductors. Here, InAlGaO-based semiconductors refers to InxAlYGazO₃ (0≤X≤2, 0≤Y≤2, 0≤Z≤2, X+Y+Z=1.5˜2.5) can be viewed as the same material system containing gallium oxide.

In recent years, gallium oxid-based p-type semiconductors have been studied. For example, Patent Literature 1 describes a base showing p-type conductivity to be obtained by forming a β-Ga₂O₃ based crystal by floating zone method using MgO (p-type dopant source). Also, Patent Literature 2 discloses to form a p-type semiconductor by using an ion implantation of p-type dopant into α-(AlₓGa₁₋ₓ)₂O₃ single crystalline film obtained by Molecular Beam Epitaxy (MBE) method. However, Non-Patent Literature 2 discloses that a p-type semiconductor was not obtained by the methods disclosed in Patent Literatures 1 and 2 (NPL2). In fact, there has been no reports of any success in forming a p-type semiconductor by use of the methods disclosed in Patent Literatures 1 and 2. Therefore, p-type oxide semiconductor and a method of manufacturing a p-type oxide semiconductor have been desired to be realized.

Also, Non-Patent Literatures 3 and 4 disclose that for example, a use of Rh₂O₃ or ZnRh₂O₄ as a p-type semiconductor has been considered. Nevertheless, Rh₂O₃ has a problem with a raw material that tends to be low in concentration especially in deposition process, and a low concentration of the raw material affects deposition. In addition, it has been difficult to produce a single crystal of Rh₂O₃ even if using an organic solvent. Also, even though Hall effect measurement was conducted, Rh₂O₃ and ZnRh₂O₄ were not determined to be p-type or the measurement itself might not be well done. Further, for example, Hall coefficient of these semiconductors were measurement limit (0.2 cm³/C) or less that was not useful at all. Also, since ZnRh₂O₄ has a low mobility and a narrow band gap, ZnRh₂O₄ cannot be used as LED or power devices. Therefore, Rh₂O₃ and ZnRh₂O₄ were not necessarily satisfactory.

As a wide band gap semiconductor besides Rh₂O₃and ZnRh₂O₄, various p-type oxide semiconductors have been investigated. Patent Literature 3 discloses that delafossite or oxychalcogenide are used as p-type semiconductor. However, the semiconductor using delafossite or oxychalcogenide has a mobility of as low as 1 cm²/Vs or less and insufficient electrical properties and thus, the semiconductor using delafossite or oxychalcogenide could not form a p-n junction properly with a next generation n-type oxide semiconductor such as α-Ga₂O₃.

Also, Ir₂O₃ has been conventionally known, for example, to be used as an iridium catalyst as disclosed in Patent Literature 4, and Patent Literature 5 discloses Ir₂O₃ is used as a dielectric, and Patent Literature 6 discloses that Ir₂O₃ is used as an electrode. However, Ir₂O₃ never been known to be used as a p-type semiconductor. Recently, the applicants have researched a use of Ir₂O₃ as a p-type semiconductor. There was a problem that in a power device with high breakdown voltage and large current, the characteristic operation of a p-type semiconductor is not stable and deteriorates electrical properties. Therefore, a semiconductor device with enhanced reliability that has enhanced stability of a semiconductor operation, has been desired.

### RELATED ART

### Patent Literature

Patent Literature 1: JP2005-340308A
Patent Literature 2: JP2013-58637A
Patent Literature 3: JP2016-25256A
Patent Literature 4: JPH09-25255A
Patent Literature 5: JPH08-227793A
Patent Literature 6: JPH11-21687A

### Non-Patent Literature

Non-Patent Literature 1: F. P. KOFFYBERG et al., “optical bandgaps and electron affinities of semiconducting Rh2O3(I) and Rh2O3(III)”, J. Phys. Chem. Solids Vol.53, No.10, pp.1285-1288, 1992

Non-Patent Literature 2: Shin-ichi Kan et al., “Electrical properties of α-Ir₂O₃/α-Ga₂O₃ pn heterojunction diode and band alignment of the heterostructure”, Appl. Phys. Lett.113, 212104(2018)

### SUMMARY OF INVENTION

### Technical Problem

An object of the disclosure is to provide a semiconductor element and/or semiconductor device having enhanced semiconductor characteristics useful as power devices.

### Solution to Problem

As a result of earnest examination to achieve the above object, the inventors found that, a semiconductor device, including: a first electrode; a second electrode; a semiconductor element; and a light emitting element, the semiconductor element including a crystal layer having a band gap that is equal to or more than 2 eV, the crystal layer that is arranged at least a part of a current pass between the first electrode and the second electrode, the light emitting element that is configured to emit light having an energy smaller than the band gap of the crystal layer, and the light emitting element that is configured to irradiate light to at least a part of the crystal layer, has enhanced reliability that has excellent electrical properties and enhanced stability of semiconductor operation. Also, the inventors found that, a semiconductor device, including: a semiconductor element; and a light emitting element; the semiconductor element including a channel-forming region, the semiconductor element including a hole-injection region that supplies holes into the channel-forming region, the hole-injection region including a p-type dopant, the semiconductor element including a crystal layer having a band gap, and the light emitting element that is configured to emit a light having an energy smaller than the band gap of the crystal layer, and the light emitting element that is configured to irradiate light to at least a part of the crystal layer, has enhanced reliability that has excellent electrical properties and enhanced stability of semiconductor operation. Further, the inventors found that, a semiconductor element, including: a first electrode; a second electrode; an n−-type semiconductor layer; and a low electrically conductive layer, the low electrically conductive layer that is arranged between the first electrode and the n−-type semiconductor layer, a first barrier height of the first electrode is larger than a second barrier height of the second electrode, a first electrical resistivity of the low electrically conductive layer is equal to or more than 1000 times as large as a second electrical resistivity of the n−-type semiconductor layer, and the semiconductor element that is configured to be able to irradiate light from an outside to at least a part of the low electrically conductive layer, has enhanced reliability that has excellent electrical properties and enhanced optical controllability of semiconductor operation. The inventors also found that the semiconductor device and/or the semiconductor element can solve the above-mentioned problem.

In addition, after learning the above findings, the inventors have made further research to complete the disclosure.

That is, the disclosure relates to the followings.
[1] A semiconductor device, including: a first electrode; a second electrode; a semiconductor element; and a light emitting element, the semiconductor element including a crystal layer having a band gap that is equal to or more than 2 eV, the crystal layer that is arranged at least a part of a current pass between the first electrode and the second electrode, the light emitting element that is configured to emit light having an energy smaller than the band gap of the crystal layer, and the light emitting element that is configured to irradiate light to at least a part of the crystal layer.
[2] A semiconductor device, including: a semiconductor element; and a light emitting element; the semiconductor element including a channel-forming region, the semiconductor element including a hole-injection region that supplies holes into the channel-forming region, the hole-injection region including a p-type dopant, the semiconductor element including a crystal layer having a band gap, and the light emitting element that is configured to emit a light having an energy smaller than the band gap of the crystal layer, and the light emitting element that is configured to irradiate light to at least a part of the crystal layer.
[3] The semiconductor device according to [1] above, wherein the crystal layer includes a crystalline oxide semiconductor as a major component.
[4] The semiconductor device according to [3] above, wherein the crystalline oxide semiconductor includes gallium and/or iridium.
[5] The semiconductor device according to [3] above, wherein the crystalline oxide semiconductor includes at least gallium.
[6] The semiconductor device according to [3] above, wherein the crystalline oxide semiconductor has a corundum structure.
[7] The semiconductor device according to [1] above, wherein the crystal layer includes a p-type dopant.
[8] The semiconductor device according to [1] above, wherein the crystal layer includes a channel-forming region, and wherein the light emitting element is configured to irradiate the light to at least a part of the channel-forming region.
[9] The semiconductor device according to [1] above, wherein the first electrode is a source electrode and the second electrode is a drain electrode.
[10] A semiconductor element, including: a first electrode; a second electrode; an n−-type semiconductor layer; and a low electrically conductive layer, the low electrically conductive layer that is arranged between the first electrode and the n−-type semiconductor layer, a first barrier height of the first electrode is larger than a second barrier height of the second electrode, a first electrical resistivity of the low electrically conductive layer is equal to or more than 1000 times as large as a second electrical resistivity of the n−-type semiconductor layer, and the semiconductor element that is configured to be able to irradiate light from an outside to at least a part of the low electrically conductive layer.
[11] The semiconductor element according to [10] above, wherein the low electrically conductive layer has a contact with the first electrode.
[12] The semiconductor element according to [10] above, wherein the n-type semiconductor layer includes a crystalline oxide semiconductor as a major component.
[13] The semiconductor element according to [12] above, wherein the crystalline oxide semiconductor includes gallium and/or iridium.
[14] The semiconductor element according to [12] above, wherein the crystalline oxide semiconductor has a corundum structure.
[15] The semiconductor element according to [12] above, wherein the crystalline oxide semiconductor has a corundum structure.
[16] The semiconductor element according to [10] above, wherein the low electrically conductive layer includes a crystalline oxide semiconductor as a major component.
[17] The semiconductor element according to [10] above, wherein the low electrically conductive layer includes a p-type dopant.
[18] The semiconductor device according to [1] above, wherein the semiconductor element is a MOSFET (Metal Oxide Semiconductor Field Effect Transistor).
[19] The semiconductor device according to [1] above, wherein the semiconductor element is a power device.
[20] The semiconductor device according to [1] above, wherein the semiconductor element
[21] A semiconductor system, including: the semiconductor device according to [1] above.

### Advantageous Effect

The semiconductor device and/or the semiconductor element according to the disclosure is useful as power devices, and has enhanced semiconductor properties.

### BRIEF DESCRIPTION OF DRAWINGS

FIG. 1 is a schematic configuration diagram illustrating a film forming apparatus (mist CVD apparatus) preferably used in the disclosure.

FIG. 2 is a schematic diagram illustrating an upper perspective view of a semiconductor device according to a preferable embodiment of the disclosure.

FIG. 3 is a schematic diagram illustrating a preferred embodiment of a power supply system.

FIG. 4 is a schematic diagram illustrating a preferred embodiment of a system device.

FIG. 5 is a schematic diagram illustrating a preferred embodiment of a power supply circuit diagram of the power supply.

FIG. 6 is a diagram illustrating a current change when switching a light in the example.

FIG. 7 is a schematic diagram illustrating an upper perspective view of a semiconductor device according to a preferable embodiment of the disclosure.

FIG. 8 is a schematic diagram illustrating a cross-sectional view of a semiconductor device according to a preferable embodiment of the disclosure.

FIG. 9 is a schematic sectional view showing a preferred semiconductor device of the present invention used in the test example.

FIG. 10 is a schematic diagram illustrating a cross-sectional view of a semiconductor device according to a preferable embodiment of the disclosure.

FIG. 11 is a diagram illustrating the results of I-V measurement in the test example.

FIG. 12 is a diagram illustrating the results of I-V measurement in the test example.

### DESCRIPTION OF EMBODIMENT

A semiconductor device according to an embodiment of the disclosure includes a first electrode; a second electrode; a semiconductor element; and a light emitting element, the semiconductor element including a crystal layer having a band gap that is equal to or more than 2 eV, the crystal layer that is arranged at least a part of a current pass between the first electrode and the second electrode, the light emitting element that is configured to emit light having an energy smaller than the band gap of the crystal layer, and the light emitting element that is configured to irradiate light to at least a part of the crystal layer. Further, a semiconductor device according to an embodiment of the disclosure, includes a semiconductor element; and a light emitting element; the semiconductor element including a channel-forming region, the semiconductor element including a hole-injection region that supplies holes into the channel-forming region, the hole-injection region including a p-type dopant, the semiconductor element including a crystal layer having a band gap, and the light emitting element that is configured to emit a light having an energy smaller than the band gap of the crystal layer, and the light emitting element that is configured to irradiate light to at least a part of the crystal layer.

The crystal layer is not particularly limited as long as the crystal layer has a band gap that is equal to or more than 2 eV. According to an embodiment of the disclosure, the crystal layer preferably has a band gap that is equal to or more than 3 eV, more preferably has a band gap that is equal to or more than 4 eV. According to an embodiment of the disclosure, it is preferable that the crystal layer contains a crystalline oxide semiconductor as a major component. The crystalline oxide semiconductor preferably contains gallium and/or iridium, and more preferably contains at least gallium. According to an embodiment of the disclosure, the crystalline oxide semiconductor preferably has a corundum structure or a β-gallia structure, and more preferably has a corundum structure. The term “major component” herein means, for example, when the crystalline oxide semiconductor is α-Ga₂O₃, α-Ga₂O₃ is contained in the crystal layer at an atomic ratio of gallium to all the metal elements contained in the crystal layer that is equal to or more than 50%. According to an embodiment of the disclosure, it is preferable that the atomic ratio of gallium to all the metal elements contained in the crystal layer is equal to or more than 70%, more preferably equal to or more than 80%. The crystal layer may be a polycrystalline layer and may be a single crystal layer. According to an embodiment of the disclosure, it is preferable that the crystal layer contains a p-type dopant. Such a preferred configuration enables to enhance operating properties of a p-type semiconductor by an irradiation of light by the light emitting element. Further, according to an embodiment of the disclosure, it is preferable that the semiconductor device further includes a channel-forming region, and the light emitting element is configured to irradiate a light to at least a part of the channel-forming region.

The crystal layer is preferably a semiconductor layer. The crystal layer is more preferably an oxide semiconductor film containing gallium oxide or a mixed crystal of gallium oxide as a major component. The oxide semiconductor film may be a p-type semiconductor film, and may be an n-type semiconductor film. Examples of gallium oxide include α-Ga₂O₃, β-Ga₂O₃, and α-Ga₂O₃, ε-Ga₂O₃. Among them, α-Ga₂O₃ is preferred. In addition, examples of the mixed crystal of gallium oxide includes a mixed crystal of gallium oxide and one or more metal oxides. Preferable examples of the metal oxide include aluminum oxide, indium oxide, iridium oxide, rhodium oxide, and iron oxide. According to an embodiment of the disclosure, it is preferable that the mixed crystal is a mixed crystal of gallium oxide and iridium oxide. The term “major component”, herein means, for example, when the oxide semiconductor film contains α-Ga₂O₃ as a major component, the atomic ratio of gallium to all the metal elements contained in the oxide semiconductor film is equal to or more than 0.5. According to an embodiment of the disclosure, it is preferable that the atomic ratio of gallium to all the metal elements contained in the oxide semiconductor film is equal to or more than 0.7, and more preferably equal to or more than 0.8. Also, for example, when the oxide semiconductor film contains α-Ga₂O₃ and α-Ir₂O₃ as a major component, a total atomic ratio of gallium and iridium to all the metal elements contained in the oxide semiconductor film is equal to or more than 0.5. According to an embodiment of the disclosure, it is preferable that the atomic ratio of gallium to all the metal elements contained in the oxide semiconductor film is equal to or more than 0.5 and more preferably equal to or more than 0.7.

A thickness of the crystal layer is not particularly limited. The thickness of the crystal layer may be equal to or less than 1 μm, and may be equal to or more than 1 μm. According to an embodiment of the disclosure, the thickness of the crystal layer is preferably equal to or more than 1 μm, more preferably in a range of from 1 μm to 40 μm, and most preferably in a range of from 1 μm to 25 μm. A surface area of the crystal layer is not particularly limited. The surface area of the crystal layer may be equal to or more than 1 mm², and may be equal to or less than 1 mm². The crystal layer may be a single layer film, or may be composed of a multilayer film.

The crystal layer is preferably an oxide semiconductor film containing a dopant. The dopant is not particularly limited unless it deviates from an object of the disclosure, and may be a known dopant. Examples of the dopant include an n-type dopant and a p-type dopant. The concentration of the dopant is preferably equal to or more than 0.00001 atomic % in a composition ratio of the oxide semiconductor film. The concentration of the dopant in the composition ratio of the oxide semiconductor film is more preferably in a range of from 0.00001 atomic % to 20 atomic %, and most preferably in a range of from 0.0001 atomic % to 20 atomic %.

The n-type dopant is not particularly limited unless it deviates from an object of the disclosure, and may be a known n-type dopant. Examples of the n-type dopant include one or more elements selected from tin, germanium, silicon, titanium, zirconium, vanadium and niobium. The p-type dopant is not particularly limited unless it deviates from an object of the disclosure, and may be a known p-type dopant. Examples of the p-type dopant includes Mg, H, Li, Na, K, Rb, Cs, Fr, Be, Ca, Sr, Ba, Ra, Mn, Fe, Co, Ni, Pd, Cu, Ag, Au, Zn, Cd, Hg, Tl, Pb, N, P and two or more elements selected therefrom. According to an embodiment of the disclosure, the p-type dopant is preferably Mg, Zn or Ca.

The semiconductor element according to an embodiment of the disclosure is a semiconductor element including: a first electrode; a second electrode; an n−-type semiconductor layer; and a low electrically conductive layer, the low electrically conductive layer that is arranged between the first electrode and the n−-type semiconductor layer, a first barrier height of the first electrode is larger than a second barrier height of the second electrode, a first electrical resistivity of the low electrically conductive layer is equal to or more than 1000 times as large as a second electrical resistivity of the n−-type semiconductor layer, and the semiconductor element that is configured to be able to irradiate light from an outside to at least a part of the low electrically conductive layer. The light is not particularly limited unless it deviates from an object of the disclosure. The light may be a visible light, may be an ultraviolet light, may be a deep ultraviolet light. According to an embodiment of the disclosure, the light is preferably a light having energy smaller than the band gap of the low electrically conductive layer. A wavelength of the light is, typically, for example, in a range of from 300 nm to 1300 nm. A source of the light is not particularly limited, and may be a known light source. According to an embodiment of the disclosure, as a light emitting element is preferably used as the source of the light. The light emitting element is not particularly limited and may be a known light emitting element such as a light emitting diode (LED). According to an embodiment of the disclosure, it is also preferable that the semiconductor device has a controlling device that controls an irradiation of the light to at least the part of the low electrically conductive layer when applying current to the semiconductor element. The term “applying current” herein means to applying a voltage so that at least 1 μA or more steady current flows to the semiconductor element. According to an embodiment of the disclosure, it is preferable that a voltage is applied so that at least 10 μA or more steady current flows in the semiconductor element. The light is not particularly limited unless it deviates from an object of the disclosure. The light may be a visible light, may be an ultraviolet light, and may be a deep ultraviolet light. According to an embodiment of the disclosure, the light is preferably a light having less energy than the band gap of the low electrically conductive layer. A wavelength of the light is, typically, for example, in a range of from 300 nm to 1300 nm. A source of the light is not particularly limited, and may be a known light source. According to an embodiment of the disclosure, as a light emitting element is preferably used as the source of the light. The light emitting element is not particularly limited and may be a known light emitting element. The control device is not particularly limited as long as the control device is capable of controlling an irradiation of the light. The control device may be a known device such as a control circuit. When the control device is the control circuit, a semiconductor system described as follows is also included in an embodiment of the disclosure. A semiconductor system, including: a semiconductor device having a semiconductor element; a control circuit, the semiconductor element including an electrically conductive layer having a band gap that is equal to or more than 3 eV, the controlling circuit that controls an irradiation of a light to at least a part of the electrically conductive layer when applying current to the semiconductor element.

The first electrode is not particularly limited as long as a first barrier height of the first electrode is larger than a second barrier height of the second electrode, and may be a known electrode. The second electrode is not particularly limited as long as the second barrier height of the second electrode is smaller than the first barrier height of the first electrode, and may be a known electrode.

When the semiconductor element includes an n-type semiconductor layer and/or n+-type semiconductor layer, a carrier concentration of the n−-type semiconductor layer is lower at more than one order than a carrier concentration of the n-type semiconductor layer and/or the n+-type semiconductor layer. More specifically, the carrier concentration of the n−type semiconductor layer is, for example, in a range of approximately equal to or less than 1×10¹⁷/cm³. According to an embodiment of the disclosure, the n-type semiconductor layer preferably contains a crystalline oxide semiconductor as a major component. The crystalline oxide semiconductor preferably contains gallium and/or iridium, and more preferably contains at least gallium. According to an embodiment of the disclosure, the crystalline oxide semiconductor preferably has a corundum structure or a β-gallia structure, and more preferably has a corundum structure. The term “major component” herein means, for example, when the crystalline oxide semiconductor is α-Ga₂O₃, the atomic ratio of gallium to all the metal elements contained in the n−-type semiconductor layer is equal to or more than 0.5. According to an embodiment of the disclosure, it is preferable that the atomic ratio of gallium to all the metal elements contained in the n-type semiconductor layer is preferably equal to or more than 0.7, and more preferably equal to or more than 0.8. The n-type semiconductor layer may be a polycrystalline layer, may be a single crystal layer. According to an embodiment of the disclosure, the n-type semiconudctor layer may be preferably a single crystal. The n-type dopant is not particularly limited unless it deviates from an object of the disclosure, and may be a known n-type dopant. Examples of the n-type dopant includes one or more elements selected from tin, germanium, silicon, titanium, zirconium, vanadium and niobium.

The low electrically conductive layer is not particularly limited, as long as a first electrical resistivity of the low electrically conductive layer is equal to or more than 100 times as large as a second electrical resistivity of the n−-type semiconductor layer. According to an embodiment of the disclosure, the low electrically conductive layer preferably has a band gap that is equal to or more than 3 eV, more preferably has a band gap that is equal to or more than 4 eV. According to an embodiment of the disclosure, the low electrically conductive layer preferably contains a crystalline oxide semiconductor as a major component. The low electrically conductive layer may be a polycrystalline layer or a single crystal layer. According to an embodiment of the disclosure, the low electrically conductive layer preferably includes a p-type dopant. Such a preferable configuration enables to enhance operation properties of a p-type semiconductor by a irradiation of the light. That is, the low electrically conductive layer may be a p-type semiconductor layer, and may be a p+-type semiconductor layer. According to an embodiment of the disclosure, it is preferable that the semiconductor element further includes a channel-forming region, and the semiconductor element is configured to be able to irradiate light to at least a part of the channel-forming region. According to an embodiment of the disclosure, the low electrically conductive layer preferably is a semiconductor layer having a contact with the first electrode. It is more preferable that the low electrically conductive layer is a semiconductor layer including the crystalline oxide semiconductor, that has a contact with the first electrode.

A thickness of the low electrically conductive layer is not particularly limited and may be equal to or less than 1 μm. According to an embodiment of the disclosure, the thickness of the low electrically conductive layer is equal to or more than 1 μm, more preferably in a range of from 1 μm to 40 μm, and most preferably in a range of from 1 μm to 25 μm. A surface area of the low electrically conductive layer is not particularly limited. The surface area of the low electrically conductive layer may be equal to or more than 1 mm², and may be equal to or less than 1 mm². The low electrically conductive layer may be a single layer film or may be a multilayer film.

According to an embodiment of the disclosure, the low electrically conductive layer contains a dopant. The dopant is not particularly limited unless it deviates from an object of the disclosure. Examples of the dopant include an n-type dopant and a p-type dopant. According to an embodiment of the disclosure, the dopant is preferably the p-type dopant. The concentration of the dopant as a composition ratio in the low electrically conductive layer is preferably equal to or more than 0.00001 atomic %, more preferably in a range of from 0.00001 atomic % to 20 atomic %, and most preferably in a range of from 0.0001 atomic % to 20 atomic %.

The n-type dopant is not particularly limited unless it deviates from an object of the disclosure, and may be a known n-type dopant. Examples of the n-type dopant include one or more elements selected from tin, germanium, silicon, titanium, zirconium, vanadium and niobium. The p-type dopant is not particularly limited unless it deviates from an object of the disclosure, and may be a known p-type dopant. Examples of the p-type dopant include Mg, H, Li, Na, K, Rb, Cs, Fr, Be, Ca, Sr, Ba, Ra, Mn, Fe, Co, Ni, Pd, Cu, Ag, Au, Zn, Cd, Hg, Tl, Pb, N, P, and two or more elements selected therefrom. According to an embodiment of the disclosure, the p-type dopant is preferably Mg, Zn or Ca.

The crystal layer (hereinafter, also referred to as “semiconductor layer” or “semiconductor film”) and/or a low electrically conductive layer may be obtained by forming a film, using an epitaxial crystal-growth method. A method of forming the film is not particularly limited. A method of epitaxial crystal-growth is not particularly limited unless it deviates from an object of the disclosure, and may be a known method. Examples of the epitaxial crystal-growth method includes CVD method, MOCVD method, MOVPE method, mist-CVD method, mist-epitaxy method, MBE method, HVPE method and pulse-growth method. According to an embodiment of the disclosure, the epitaxial crystal-growth method is preferably a mist CVD method or a mist epitaxy method.

According to an embodiment of the disclosure, it is preferable that the film formation is performed by atomizing a raw material solution containing a metal (atomization step), carrying the obtained atomized droplets by using a carrier gas to a vicinity of a base (carrying step), and thermally reacting the atomized droplets (film forming step).

### (Raw Material Solution)

The raw material solution is not particularly limited as long as the atomized droplets can be formed from the raw material solution and as long as the raw material solution includes a metal as a raw material (film-forming material). The raw material may be an inorganic material or an organic material. According to one or more embodiments of the disclosure, the metal may be a single metal or a metal compound. Examples of the metal includes one or more metals selected from gallium (Ga), iridium (Ir), indium (In), rhodium (Rh), aluminum (Al), gold (Au), silver (Ag), platinum (Pt), copper (Cu), iron (Fe), manganese (Mn), nickel (Ni), palladium (Pd), cobalt (Co), ruthenium (Ru), chromium (Cr), molybdenum (Mo), tungsten (W), tantalum (Ta), zinc (Zn), lead (Pb), rhenium (Re), titanium (Ti), tin (Sn), gallium (Ga), magnesium (Mg), calcium (Ca) and zirconium (Zr). According to an embodiment of the disclosure, the metal preferably contains at least a metal selected from 4^{th} period to 6^{th} period of the periodic table, more preferably contains a metal selected from gallium, indium, aluminum, rhodium and iridium, and most preferably contains gallium. By using such a preferable metal, an epitaxial film may be formed, that is preferably applied to semiconductor devices.

According to one or more embodiments of the disclosure, a raw material solution containing at least one metal, in a form of complex or salt, dissolved or dispersed in an organic solvent or water may be used. Examples of the form of the complex include an acetylacetonate complex, a carbonyl complex, an ammine complex and a hydride complex. Examples of the form of the salt includes an organic metal salt (e.g., metal acetate, metal oxalate, metal citrate, etc.), metal sulfide, metal nitrate, phosphorylated metal and metal halide (e.g., metal chloride, metal bromide, metal iodide, etc.).

A solvent of the raw material solution is not particularly limited unless it deviates from an object of the disclosure. The solvent may be an inorganic solvent such as water. The solvent may be an organic solvent such as alcohol. Also, the solvent may be a mixed solvent of the inorganic solvent and the organic solvent. According to one or more embodiments of the disclosure, the solvent preferably includes water. According to one or more embodiments of the disclosure, the solvent is more preferably water.

Further, raw material solution may contain a hydrohalic acid and/or an oxidant as an additive. Examples of the hydrohalic acid include hydrobromic acid, hydrochloric acid and hydroiodic acid. Among all, hydrobromic acid or hydroiodic acid may be preferable for a reason to obtain a film of better quality. Examples of the oxidant include hydrogen peroxide (H₂O₂), sodium peroxide (Na₂O₂), barium peroxide (BaO₂), a peroxide including benzoyl peroxide (C₆H₅CO)₂O₂, hypochlorous acid (HClO), perchloric acid, nitric acid, ozone water, and an organic peroxide such as peracetic acid and nitrobenzene.

The raw material solution may contain a dopant. The dopant is not particularly limited unless it deviates from an object of the disclosure. Examples of the dopant include the above-mentioned n-type dopant and the p-type dopant. The dopant concentration in general may be approximately in a range of from 1×10¹⁶/cm³ to 1×10²²/cm³. The dopant concentration may be at a lower concentration of, for example, approximately equal to or less than 1×10¹⁷/cm³. According to one or more embodiments of the disclosure, the dopant may be contained at a high concentration of, for example, approximately equal to or more than 1×10²⁰/cm³. According to one or more embodiments of the disclosure, it is preferable that the dopant is contained in a carrier concentration of equal to or more than 1×10¹⁷/cm³.

### (Atomization Step)

At an atomization step, the raw material solution is turned into atomized droplets. A method of forming atomized droplets from the raw material solution is not particularly limited, as long as the raw material solution is able to be turned into atomized droplets, and may be a known method. According to one or more embodiments of the disclosure, a method of forming atomized droplets using ultrasonic vibration is preferable. Atomized droplets including mist particles and obtained by using ultrasonic vibration and floating in the space have the initial velocity that is zero. Since atomized droplets floating in the space is carriable as a gas, the atomized droplets floating in the space are preferable to avoid damage caused by the collision energy without being blown like a spray. The droplet size is not particularly limited and may be a droplet of about several millimeters, but is preferably 50 μm or less, and more preferably 100 nm to 10 μm.

### (Carrying Step)

At a carrying step, the atomized droplets are delivered to a base by using a carrier gas. The carrier gas is not particularly limited unless it deviates from an object of the disclosure. Examples of the carrier gas includes oxygen, ozone, an inert gas such as nitrogen or argon and a reduction gas such as hydrogen gas or a forming gas. Further, the carrier gas may contain one or two or more gasses. Also, a diluted gas (e.g., 10-fold diluted carrier gas) and the like may be further used as a second carrier gas. The carrier gas may be supplied from one or more locations. A flow rate of the carrier gas is not particularly limited. The flow rate of the carrier gas is preferably in a range of from 0.01 L/min to 20 L/min and more preferably in a range of from 1 L/min to 10 L/min. For the diluted carrier gas, a flow rate of the dilute carrier gas may be preferably in a range of from 0.001 L/min to 2 L/min, and more preferably in a range of from 0.1 L/min to 1 L/min.

### (Film Forming Step)

At a film forming step, the semiconductor film is formed on the base by a thermal reaction of the atomized droplets. The thermal reaction is not particularly limited as long as the atomized droplets react with heat. Reaction conditions and the like are not particularly limited unless it deviates from an object of the disclosure. In the film forming step, the thermal reaction is in general carried out at an evaporation temperature of the solvent of the raw material solution or at a higher temperature than the evaporation temperature. The temperature during the thermal reaction is equal to or less than a too high temperature (for example, 1000° C.), and preferably equal to or less than 650° C., and more preferably in a range of from 300° C. to 650° C. Further, the thermal reaction may be conducted, unless it deviates from an object of the disclosure, in any atmosphere of a vacuum, a non-oxygen atmosphere, a reducing gas atmosphere and an oxygen atmosphere. According to an embodiment of the disclosure, the thermal reaction may be preferably conducted in a non-oxygen atmosphere or an oxygen atmosphere. Further, the thermal reaction may be conducted in any conditions of under atmospheric pressure, under increased pressure, and under a reduced pressure. According to one or more embodiments of the disclosure, the thermal reaction may be preferably conducted under an atmospheric pressure. Further, a film thickness can be set by adjusting a film forming time.

### (Base)

A base is not particularly limited as long as the base can support the semiconductor film. A material of the base is not particularly limited unless it deviates from an object of the disclosure, and may be a known base. The base may be an organic compound, or may be an inorganic compound. The base may be in any shape, and can perform for any shape. Examples of the shape of the base includes plate such as flat plate or a disc, fibrous, bar, columnar, prismatic, cylindrical, spiral, spherical and annular. According to one or more embodiments of the disclosure, the base is preferably a substrate. A thickness of the substrate is not particularly limited according to one or more embodiments of the disclosure.

The substrate is not particularly limited as long as the substrate is in the shape of plate and can support the semiconductor film. The substrate may be an insulator substrate or a semiconductor substrate. The substrate may be an insulator substrate, a semiconductor substrate, a metal substrate or a conductive substrate. According to an embodiment of the disclosure, the substrate is preferably an insulator substrate. It is also preferable that the substrate may have a metal film on a surface thereof. Examples of the substrate include a substrate including a substrate material with a corundum structure as a major component, a substrate including a substrate material with a (β-Gallia structure as a major component or a substrate including a substrate material with a hexagonal structure as a major component. The term “major component” herein means that the substrate preferably contains a substrate material with a particular crystalline structure at an atomic ratio of 50% or more to all components of a substrate material contained in the substrate. The substrate preferably contains the substrate material with the particular crystalline structure at an atomic ratio of 70% or more to all components of the substrate material contained in the substrate and more preferably contains at an atomic ratio of 90% or more. The substrate may contain the substrate material with the particular crystalline structure at an atomic ratio of 100% to all components of the substrate material contained in the substrate.

A substrate material is not particularly limited as long as it deviates from an object of the disclosure, and may be a known substrate material. Examples of the substrate material with the corundum structure include β-Al₂O₃ (sapphire substrate) or α-Ga₂O₃. Also, preferable examples of the substrate material with the corundum structure include an a-plane sapphire substrate, an m-plane sapphire substrate, an r-plane sapphire substrate, a c-plane sapphire substrate and an α-type gallium oxide substrate (a-plane, m-plane or r-plane). Examples of the substrate including the substrate material with the β-Gallia structure as a major component include a β-Ga₂O₃ substrate or a mixed crystal substrate containing Al₂O₃ and Ga₂O₃ where Al₂O₃ is more than 0 wt % and equal to or less than 60 wt %. Examples of the substrate including the substrate material with a hexagonal structure include a SiC substrate, a ZnO substrate and a GaN substrate.

According to one or more embodiments of the disclosure, annealing may be performed after the deposition step. An annealing temperature is not particularly limited unless it deviates from an object of the disclosure. The annealing temperature may be generally in a range of from 300° C. to 650° C., and may be preferably in a range of from 350° C. to 550° C. An annealing time is generally in a range of from 1 minute to 48 hours, preferably in a range of from 10 minutes to 24 hours, and more preferably in a range of from 30 minutes to 12 hours. The annealing may be performed in any atmosphere unless it deviates from an object of the disclosure. According to an embodiment of the disclosure, the thermal reaction is preferably performed in a non-oxygen atmosphere, more preferably performed in a nitrogen atmosphere.

According to one or more embodiments of the disclosure, the semiconductor film may be provided directly on the base, or may be provided via another layer such as a buffer layer or a stress relief layer. A forming method of each layer is not particularly limited and may be a known method, however, a mist CVD method is preferred according to one or more embodiments of the disclosure.

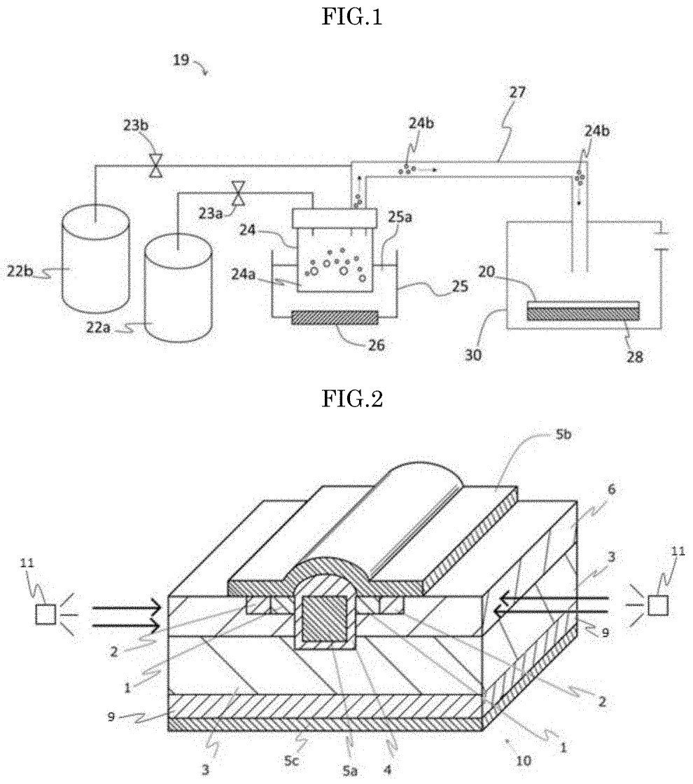

Hereinafter, with reference to drawings, a deposition apparatus 19 used in an embodiment of the present invention is described. The deposition apparatus 19 of FIG. 1 includes a carrier gas source 22a to supply a carrier gas, a flow control valve 23a that is configured to control a flow rate of the carrier gas supplied from the carrier gas source 22a, a carrier gas (diluted) source 22b to supply a carrier gas (diluted), a flow control valve 23b that is configured to control a flow rate of the carrier gas supplied (diluted) from the carrier gas (diluted) source 22b, a mist generator 24 containing a raw material solution 24a, a container 25 containing water 25a, an ultrasonic transducer 26 attached to a bottom of the container 25, a deposition chamber 30, a quartz supply pipe 27 connecting from the mist generator 24 to the deposition chamber 30, and a hot plate (heater) 28 arranged in the deposition chamber 30. A substrate 20 may be set on the hot plate 28.

Then, as described in FIG. 1, the raw material solution 24a is set in the mist generator 24. The substrate 20 is placed on the hot plate 28. The hot plate 28 is activated to raise a temperature in the deposition chamber 30. Then, the flow control valve 23 (23a, 23b) is opened to supply the carrier gas from the carrier gas source 22 (22a, 22b) into the deposition chamber 30. After the atmosphere in the deposition chamber 30 is sufficiently replaced with the carrier gas, the flow rate of the carrier gas and the carrier gas (diluted) are adjusted respectively. The ultrasonic transducer 26 is then vibrated, and a vibration propagate through the water 25a to the raw material solution 24a to atomize the raw material solution 24a to generate atomized droplets 24b. The atomized droplets 24b are introduced into the deposition chamber 30 by the carrier gas, and is delivered to the substrate 20. Then, under an atmospheric pressure, the atomized droplets 24b in the deposition chamber 30 is thermally reacted to form a film on the substrate 20.

According to an embodiment of the disclosure, the film obtained in the film forming step may be used as a crystal layer in the semiconductor element as it is. According to an embodiment of the disclosure, the film obtained in the film forming step may be used as a crystal layer in the semiconductor element after going through a known method such as peeling off from the base.

According to an embodiment of the disclosure, the semiconductor element may include an insulating substrate and may be a horizontal semiconductor element. According to another embodiment of the disclosure, the semiconductor element may be a vertical semiconductor element. The vertical semiconductor element may be provided with an electrically conductive substrate.

The semiconductor element is especially useful for power devices. Examples of the semiconductor element includes a transistor. According to an embodiment of the disclosure, the semiconductor element may be preferably a MOSFET (Metal Oxide Semiconductor Field Effect Transistor). Further, the semiconductor element is preferably a normally off device.

Example of the transistor include a semiconductor element including at least the crystal layer, a gate insulating film, a gate electrode, a source electrode (first electrode) and a drain electrode (second electrode). According to an embodiment of the disclosure, it is preferable that the crystal layer includes a channel-forming region, and more preferably includes an inversion channel-forming region. When the crystal layer includes a channel-forming region, the light emitting element is preferably configured to be capable of irradiating the light to at least a part of the channel-forming region. According to an embodiment of the disclosure, the semiconductor element may be preferably a vertical device, in that, the semiconductor layer is arranged between the source electrode and the drain electrode.

The inversion channel-forming region is, typically, provided between semiconductor regions having different types of conductivity to each other. For example, when the inversion channel-forming region is provided in the p-type semiconductor layer, the inversion channel-forming region is provided between semiconductor regions made of n-type semiconductors. Also, when the inversion channel-forming region is provided in the n-type semiconductor layer, the inversion channel-forming region is provided between semiconductor regions made of p-type semiconductors. A method of forming each semiconductor region may be the same as the method of forming the crystal layer.

Also, according to an embodiment of the disclosure, an oxide film containing at least an element selected from elements of the Group 15 in the periodic table is preferably arranged on the inversion channel region. As the element, examples of the element include nitrogen (N) and phosphorus (P), and according to an embodiment of the disclosure, nitrogen (N) or phosphorus (P) is preferable, and phosphorus (P) is more preferable. For example, an oxide film containing at least phosphorous, that is positioned between the gate insulation film and the inversion channel region and arranged on the inversion channel region, prevents hydrogen from diffusing into the oxide semiconductor film, and since it is also possible to lower interface state, a semiconductor device, especially a semiconductor device with a wide band gap semiconductor, is able to obtain an enhanced semiconductor characteristic. According to an embodiment of the disclosure, the oxide film further preferably contains at least one of the elements of the Group 15 in the periodic table and one or two or more metals of the Group 13 of the periodic table. Examples of the metal include aluminum (Al), gallium (Ga), and indium (In), and particularly, Ga and/or Al is preferable, and Ga is further preferable. Also, the oxide film is preferably a thin film to be 100 nm or less in thickness, and most preferably a film that is 50 nm or less in thickness. The arrangement of such an oxide film makes it possible to further effectively suppress the gate leakage current and to obtain further enhanced semiconductor characteristics. As a method of forming the oxide film, for example, a known method may be used, and more specifically, examples of the method include a dry method and a wet method, however, surface treatment by phosphoric acid, for example, on the inversion channel region is preferable.

Further, according to an embodiment of the disclosure, a gate electrode may be preferably provided through a gate insulation film on and/or above the inversion channel region and the oxide film. Such a preferable configuration enables to more easily suppress a diffusion of hydrogen and enables more enhanced semiconductor properties.

The gate insulation film is not particularly limited unless it deviates from an object of the disclosure, and may be a known insulation film. As the gate insulation film, preferable examples include films osf SiO₂, Si₃N₄, Al₂O₃, GaO, AlGaO, InAlGaO, AlInZnGaO₄, AlN, Hf₂O₃, SiN, SiON, MgO, and GdO, and oxide film (e.g., an oxide film containing at least phosphorus). The method of forming the gate insulation film may be a known method, and examples of the known method include a dry method and a wet method. Examples of the dry method include known methods such as sputtering, vacuum deposition, CVD (Chemical Vapor Deposition), ALD (Atomic Laser Deposition), and PLD (Pulsed Laser Deposition). Examples of the wet method include a method of application such as screen printing or die coating.

The gate electrode may be a known gate electrode, and material(s) of the electrode may be an electrically-conductive inorganic material, and also may be an electrically-conductive organic material. According to an embodiment of the disclosure, the material(s) of the electrode is preferably a metal, and the metal is not particularly limited, however, at least one metal selected from metals of Group 4 to Group 11 in the periodic table. Examples of the metal of the Group 4 in the periodic table include titanium (Ti), zirconium (Zr), and hafnium (Hf), and particularly, Ti is preferable. Examples of the metal of Group 5 in the periodic table include vanadium (V), niobium (Nb), and tantalum (Ta). Examples of the metal of Group 6 in the periodic table include chromium (Cr), molybdenum (Mo), and tungsten (W), and one or two or more metals may be selected from, however, in the present inventive subject matter, Cr is more preferable because semiconductor properties including a switching characteristic become better. Examples of the metal of Group 7 in the periodic table include manganese (Mn), technetium (Tc), and Rhenium (Re). Examples of the metal of Group 8 in the periodic table include iron (Fe), ruthenium (Ru), and osmium (Os). Examples of the metal of Group 9 in the periodic table include cobalt (Co), rhodium (Rh), and iridium (Ir). Also, examples of the metal of Group 10 in the periodic table include nickel (Ni), palladium (Pd), and platinum (Pt), and particularly, Pt is preferable. Examples of the metal of Group 11 in the periodic table include copper (Cu), silver (Ag), and gold (Au). The method of forming the gate electrode may be, for example, a known method, and more specifically, examples of the method include a dry method and a wet method. As the dry method, for example, sputtering, vacuum deposition, or CVD may be mentioned as a known method. As the wet method, for example, screen printing or die coating may be mentioned.

According to an embodiment of the disclosure, not only the gate electrode, the semiconductor element includes a source electrode as a first electrode, and a drain electrode as a second electrode. The source electrode may be a known source electrode. The drain electrode may be a known drain electrode. Also, a forming method of each electrode may be a known method.

The semiconductor device according to an embodiment of the disclosure includes, in addition to the semiconductor element, a light emitting element that emits a light having an energy smaller than the band gap of the crystal layer. The light emitting element is configured to be capable of irradiating the light to at least a part of the crystal layer. The light emitting element is not particularly limited as long as the light emitting layer is configured so as to be capable of irradiating at least a part of the crystal layer, and may be a known light emitting element. Examples of the light emitting element includes an LED (Light Emitting Diode). More specifically, for example, the light emitting element may be a known light emitting element having an anode, a cathode, and a light emitter arranged between the anode and the cathode. The semiconductor device according to an embodiment of the disclosure, usually, has an optical path that is provided between the light emitting element and the semiconductor element. The optical path may be provided by using light-transmitting material. A length of the optical path is not particularly limited, and is preferably equal to or less than 10 mm.

According to an embodiment of the disclosure, the semiconductor device may be preferably configured to be able to irradiate the light that is reflected in the semiconductor element to at least a part of the crystal layer. According to an embodiment of the disclosure, it is more preferable that the crystal layer has an interface that satisfies the total internal reflection condition. The term “reflection” herein may be a specular reflection or a diffuse reflection. The reflection includes a scattering of light that changes a path of light into various directions, not only a change of light in one direction. A reflected object to which the light is reflected is not particularly limited as long as the reflected object is located in the semiconductor element. According to an embodiment of the disclosure, the reflective object is preferably an electrode or a dielectric film. Also, examples when the crystal layer has the interface that satisfies the total internal reflection condition includes the case that the semiconductor element further includes a dielectric film, and an interface between the crystal layer and the dielectric film satisfies the total internal reflection condition. The term “the total internal reflection condition” herein means that the total reflection condition defined by refractive index of the crystal layer and the dielectric film. The dielectric film is not particularly limited, and may be a known dielectric film. Although a relative dielectric constant of the dielectric film is not particularly limited, the relative dielectric constant is preferably equal to or less than five. The term “relative dielectric constant” herein means a ratio of a dielectric constant of a film to a dielectric constant of vacuum. Examples of the dielectric film includes an oxide film, a phosphorus oxide film and a nitride film. According to an embodiment of the disclosure, it is preferable that the dielectric film is a film containing Si. Preferred examples of the film containing Si include a silicon oxide-based film. Examples of the silicon oxide-based film include a SiO₂ film, a Phosphorus-added SiO₂ (PSG) layer, a boron-added SiO₂ layer, a Phonboron-added SiO₂ layer (BPSG layer), a SiOC layer, and a SiOF layer. A method of forming the dielectric film is not particularly limited. Examples of the method of forming the dielectric film include CVD method, atmospheric pressure CVD method, plasma CVD method, mist CVD method, and thermal oxidation method. According to an embodiment of the disclosure, the method of forming the dielectric film is preferably mist CVD method or atmospheric pressure CVD method. A film thickness of the dielectric film is not particularly limited. The film thickness of the dielectric film may be preferably equal to or more than 1 μm. According to an embodiment of the disclosure, it is also preferable that the dielectric film is used as a gate insulating film.

Hereinafter, preferred embodiments of the disclosure will be described more specifically with reference to the drawings, however, the disclosure is not limited thereto.

### (MOSFET)

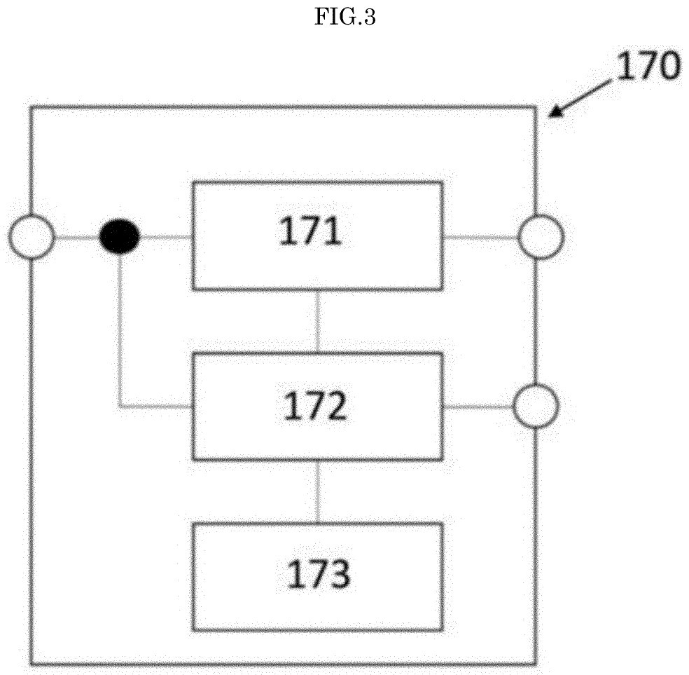

Specific examples of the semiconductor device according to an embodiment of the disclosure include a MOSFET (a semiconductor element) and a light emitting element (a source of light) illustrated in FIG. 2. The MOSFET of FIG. 2 is a vertical MOSFET including an n+-type semiconductor layer (a semiconductor layer) 1, p+-type semiconductor layer (semiconductor layer) 2, n-type semiconductor layer (a semiconductor layer) 3, p-type semiconductor layer (crystal layer) 6, n+-type semiconductor layer 9, a gate insulating film 4, a gate electrode 5a, a source electrode (first electrode) 5b, and a drain electrode (second electrode) 5c. At least a part of the gate electrode 5a may be embedded in the p-type semiconductor layer 6 and/or the n-type semiconductor layer 3. According to an embodiment of the disclosure, all of the gate electrode 5a may be embedded in the p-type semiconductor layer 6 and/or the n-type semiconductor layer 3 as illustrated in FIG. 2. In a vicinity of the gate electrode 5a, the n+-type semiconductor layer 1 and the p+-type semiconductor layer 2 are embedded respectively in the p-type semiconductor layer 6. The source electrode 5b is arranged on the n-type semiconductor layer 1 and p+-type semiconductor layer 2. Also, the semiconductor device of FIG. 2 is provided with a light emitting element (a source of light) 11 in addition to MOSFET (a semiconductor element), and is configured to irradiate a light to a direction of an arrow illustrated in FIG. 2.

In an on-state of MOSFET of FIG. 2, light from the light emitting element (light source) 11 is irradiated to the direction of the arrow. By irradiating the light to the p-type semiconductor layer 6, a generation of holes is activated and electrical properties of the p-type semiconductor layer 6 is enhanced. By applying a voltage between the source electrode 5b and the drain electrode 5c so that a positive voltage against the source electrode 5b is applied to the gate electrode, at the same time with the above-mentioned irradiating the light, a channel layer is formed in the p-type semiconductor layer 6 and the semiconductor element turns on. In an off state, by stopping the irradiation of light to suppress the generation of holes and by controlling the voltage of the gate electrode 5a to be 0 V, the channel layer is not formed and the semiconductor element turns off.

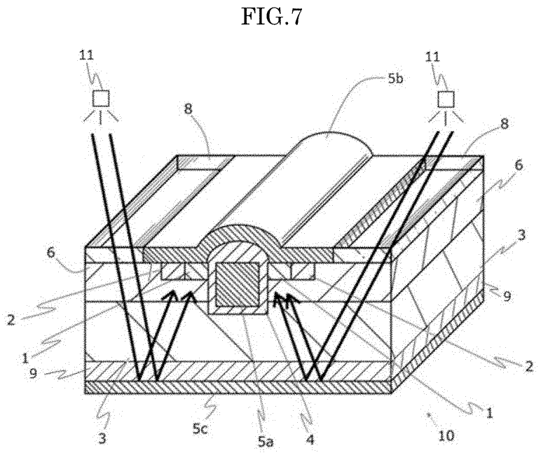

A MOSFET of FIG. 7 differs from the MOSFET of FIG. 2 in that the MOSFET of FIG. 7 includes a transparent electrode 8. By using such a transparent electrode 8 in this way, holes are more effectively generated, and it is possible to obtain better semiconductor properties. The transparent electrode 8 is not particularly limited as long as the transparent electrode is made of a light-transmitting electrode having electrically conductive and translucent property, and may be a known transparent electrode. A degree of translucency of the transparent electrode is not particularly limited unless it deviates from an object of the disclosure. Examples of a material of the translucent electrode include an electrically conductive material such as an oxide containing indium (In) or titanium (Ti). More specifically, examples of the translucent electrode include In₂O₃, ZnO, SnO₂, Ga₂O₃, TiO₂, CeO₂, a mixed crystal thereof, and a doped oxide thereof. The translucent electrode may be formed by providing the above-mentioned material by using a known method such as sputtering. Also, after forming the translucent electrode, a thermal annealing may be conducted that aims for the purpose of enhancing a transparency of the translucent electrode. By using the transparent electrode 8 as described above, even when the semiconductor element is a vertical device, without impairing the semiconductor characteristics of the semiconductor element, the light reflected in the semiconductor element is possible to be more easily irradiated to at least a part of the crystal layer.

The MOSFET of FIG. 7 is a vertical MOSFET including an n+-type semiconductor layer (a semiconductor layer) 1, a p+-type semiconductor layer (a semiconductor layer) 2, an n-type semiconductor layer (a semiconductor layer) 3, a p-type semiconductor layer (a crystal layer) 6, an n+-type semiconductor layer 9, a gate insulating film 4, a gate electrode 5a, a source electrode 5b, a drain electrode 5c and a transparent electrode 8. According to an embodiment of the disclosure, at least a part of the gate electrode 5a may be embedded in the p-type semiconductor layer 6 and/or the n-type semiconductor layer 3. According to an embodiment of the disclosure, all of the gate electrode may be embedded in the p-type semiconductor layer 6 and/or the n-type semiconductor layer 3, as illustrated in FIG. 7. In a vicinity of the gate electrode 5a, the n+-type semiconductor layer 1 and p+-type semiconductor layer 2 are embedded respectively in the p-type semiconductor layer 6. The source electrode 5b is arranged on the n-type semiconductor layer 1 and the p+-type semiconductor layer 2. Also, the transparent electrode 8 is arranged next to the source electrode 5b. The MOSFET (semiconductor element) of FIG. 7 is configured in that a light irradiated from the light emitting element (source of light) 11 in a direction of the arrow in FIG. 7 is reflected by the drain electrode 5c. In an on-state of the MOSFET of FIG. 7, a light from the light emitting element (light source) 11 is irradiated in the direction of the arrow in FIG. 7, is reflected by the drain electrode 5c through the transparent electrode 8. The reflected light is irradiated to the semiconductor layer, so that the electrical properties of the semiconductor layer is improved. In an off state, by stopping the irradiation of light to suppress the generation of holes and by controlling the voltage of the gate electrode 5a to be 0 V, the channel layer is not formed and the semiconductor element turns off. According to an embodiment of the disclosure, the light may be the reflected light that is reflected in the semiconductor element. The term “reflection” herein may be a specular reflection or a diffuse reflection. The reflection includes a scattering of light that changes a path of light into various directions, not only a change of light in one direction. A reflected object to which the light is reflected is not particularly limited as long as the reflected object is located in the semiconductor element. According to an embodiment of the disclosure, the reflective object is preferably an electrode or a dielectric film (a gate insulating film).

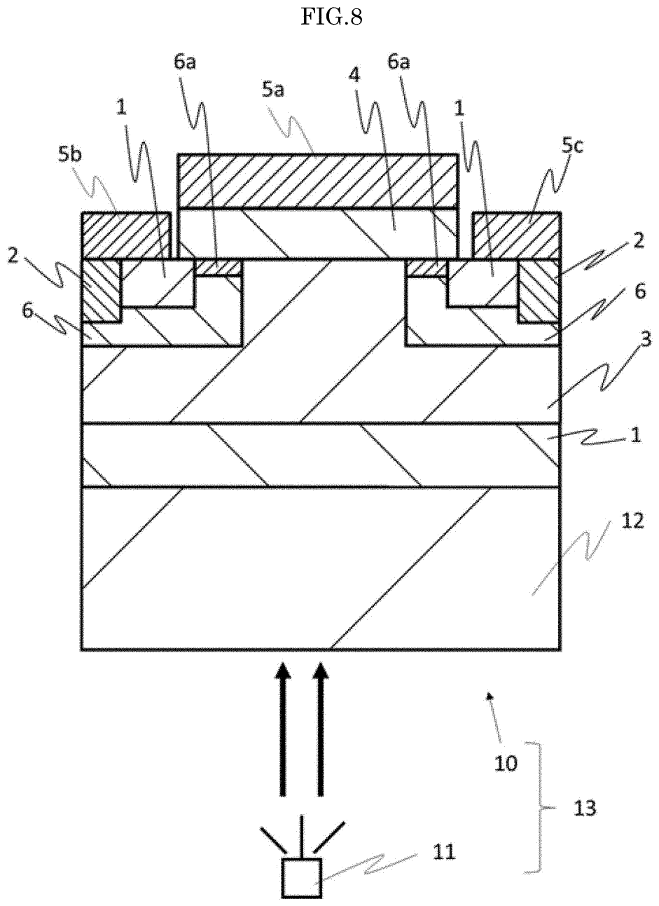

A MOSFET of FIG. 8 is an embodiment of a horizontal MOSFET including a substrate 12, an n+-type semiconductor layer (a semiconductor layer) 1, a p+-type semiconductor layer (low electrically conductive layer) 2, an n−-type semiconductor layer (a semiconductor layer) 3, p-type semiconductor layer (low conductive layer) 6, a gate insulating film 4, a gate electrode 5a, a source electrode 5b and a drain electrode 5c. The substrate 12 is usually a transparent substrate (for example, a sapphire substrate), and is configured to be able to be irradiated a light from outside through the substrate 12. Also, the semiconductor device of FIG. 8 is provided with a light emitting element (a source of light) 11 in addition to MOSFET (a semiconductor element), and is configured to irradiate a light to a direction of an arrow illustrated in FIG. 8. In an on-state of MOSFET of FIG. 8, light from the light emitting element (light source) 11 is irradiated to the direction of the arrow. By irradiating the light to the p-type semiconductor layer 6, a generation of holes is activated and electrical properties of the p-type semiconductor layer 6 is enhanced. By applying a voltage between the source electrode 5b and the drain electrode 5c so that a positive voltage against the source electrode 5b is applied to the gate electrode, at the same time with the above-mentioned irradiating the light, a channel layer 6a is formed in the p-type semiconductor layer 6 and the semiconductor element turns on. In an off state, by stopping the irradiation of light to suppress the generation of holes and by controlling the voltage of the gate electrode 5a to be 0 V, the channel layer is not formed and the semiconductor element turns off.

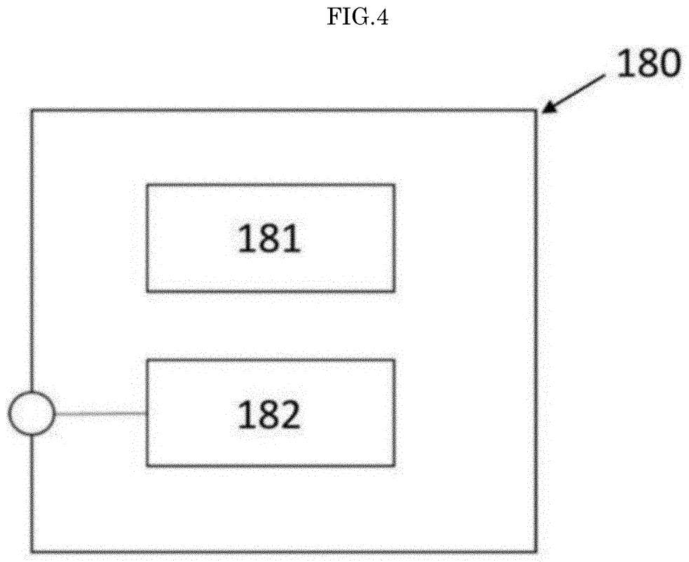

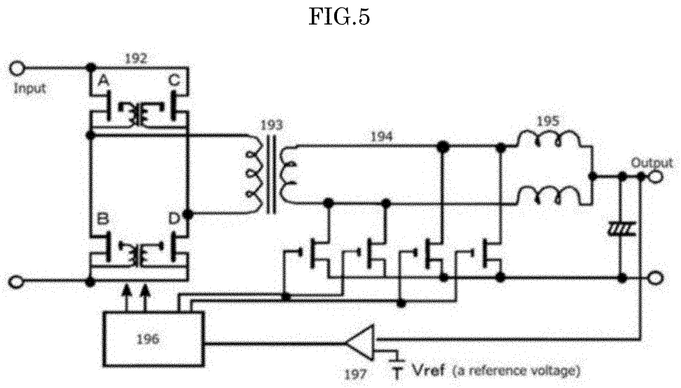

In addition, the semiconductor device according to the disclosure may be used as a power module, an inverter, and/or a converter in combination with a known structure. Also, a semiconductor device according to the disclosure may be used in a semiconductor system including a power source, to which the semiconductor device may be electrically connected by a known structure and/or method. The semiconductor device may be electrically connected to a wiring pattern in the semiconductor system. FIG. 3 is a schematic view of a circuit diagram illustrating a power source system according to one or more embodiments of the disclosure. FIG. 3 illustrates a schematic view of the power source system using two or more power source devices and a control circuit. The power source system is, as illustrated in FIG. 4, used for a system device in combination with a circuit diagram. Also, FIG. 5 illustrates a power source circuit of a power source device, including a power circuit and a control circuit. A DC voltage is switched at high frequencies by an inverter (configured with MOSFET A to D) to be converted to AC, followed by insulation and transformation by a transformer. The voltage is then rectified by a rectification MOSFET and then smoothed by a DCL (smoothing coils L1 and L2) and a capacitor to output a direct current voltage. At this point, the output voltage is compared with a reference voltage by a voltage comparator to control the inverter and the rectification MOSFETs by a PWM control circuit to have a desired output voltage.

### EXAMPLE

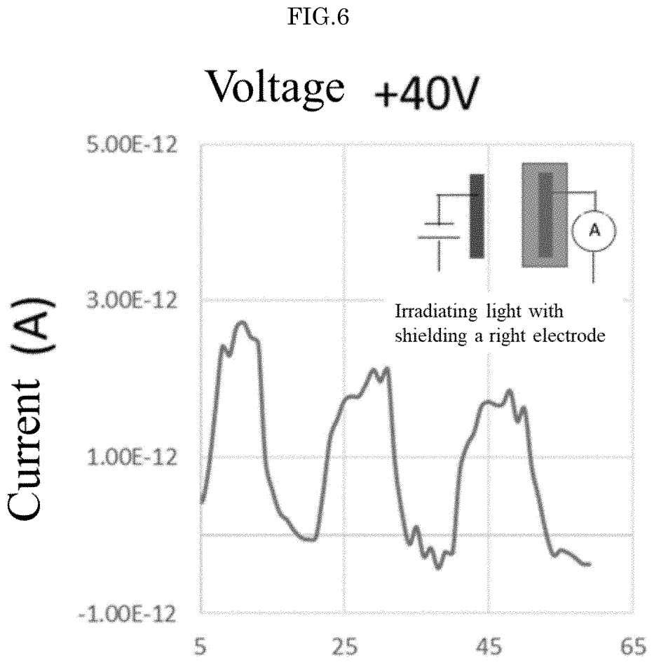

A prototype was prepared according to the MOSFET illustrated in FIG. 2, and a test evaluation was conducted under the following conditions. As the p-type semiconducting layer, Mg-doped α-Ga₂O₃ was used. Ti was used for each electrode. As a light emitting element (light source), a laser light source was used. A wavelength of the irradiated light was 638 nm, and an intensity was 100 mW. Also, a distance between the source electrode and the drain electrode was 1 mm. The result of light irradiation with shielding the drain electrode is illustrated in FIG. 6. As is apparent from FIG. 6, the electrical resistivity was lowered by irradiation of light, in particular, a generation of holes was activated. In addition, the similar results were obtained when Ru or Pt was used as each electrode. The similar results regarding the electrical resistivity and the activation of generation of holes were obtained when adjusting the wavelength of the irradiated light to be in a range of from 300 nm to 1300 nm, and the intensity to be in a range of from 1 mW to 200 mW.

### Test Example 1

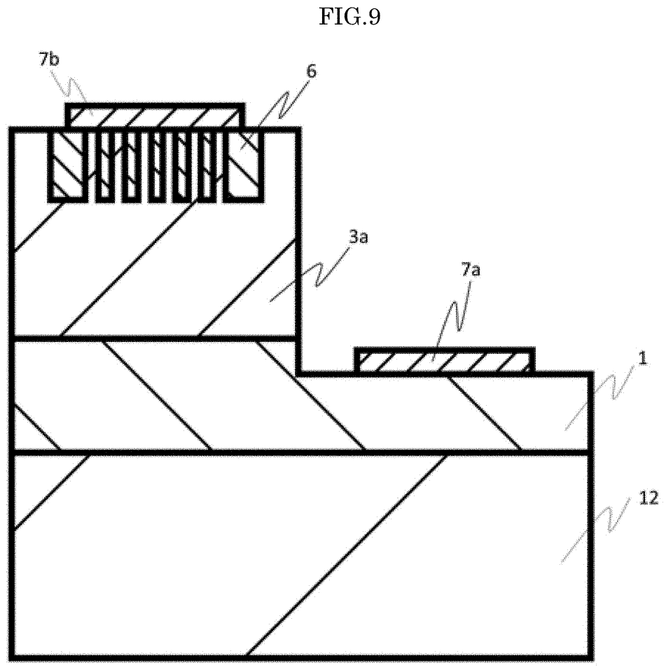

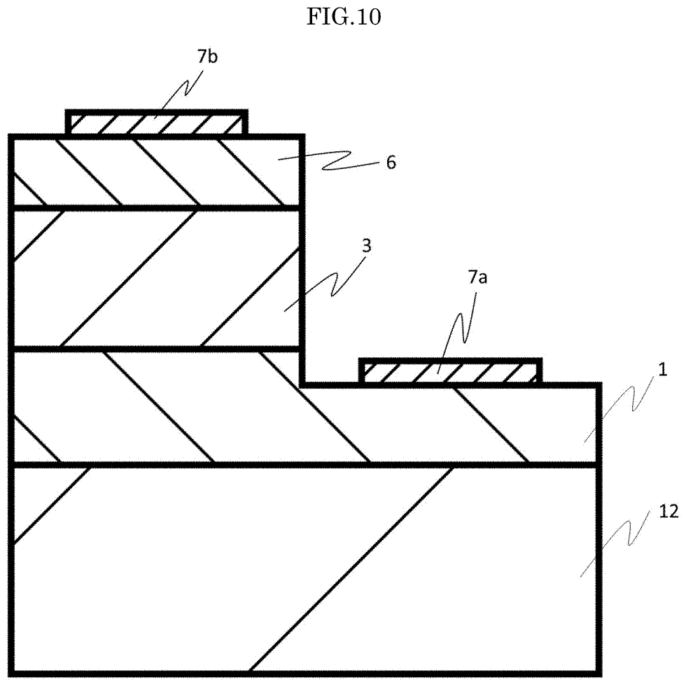

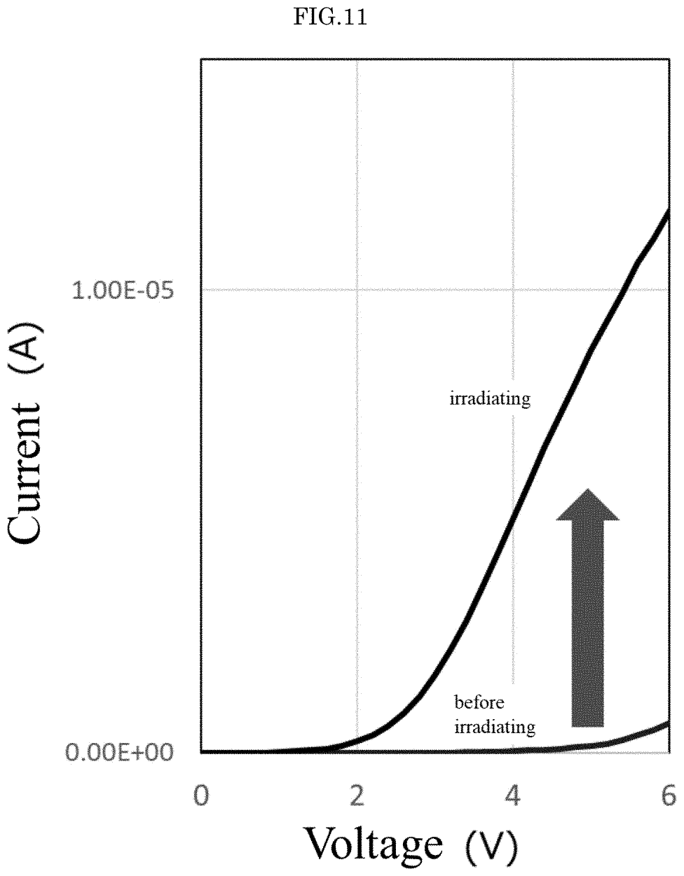

A prototype was prepared according to the semiconductor element (JBS) illustrated in FIG. 9, and a test evaluation was conducted under the following conditions. As a substrate, a sapphire substrate was used. As the low electrically conductive layer, Mg-doped α-Ga₂O₃ was used. Sn-doped α-Ga₂O₃ was used as the n+-type layer. Sn-doped α-Ga₂O₃ was used as the n−-type semiconductor layer. Ti was used as the Ohmic electrode and Co was used as the Schottky electrode. As a light emitting element (light source), a lamp light source was used. A wavelength of the irradiated light was set to be 300 nm, and an intensity was set to be 1 mW. The results of I-V measurement before and after light irradiation are illustrated in FIG. 11. As is apparent from FIG. 11, the electrical resistivity is lowered by irradiation of light, and the electrical conductivity of the semiconductor element was increased.

### Test Example 2

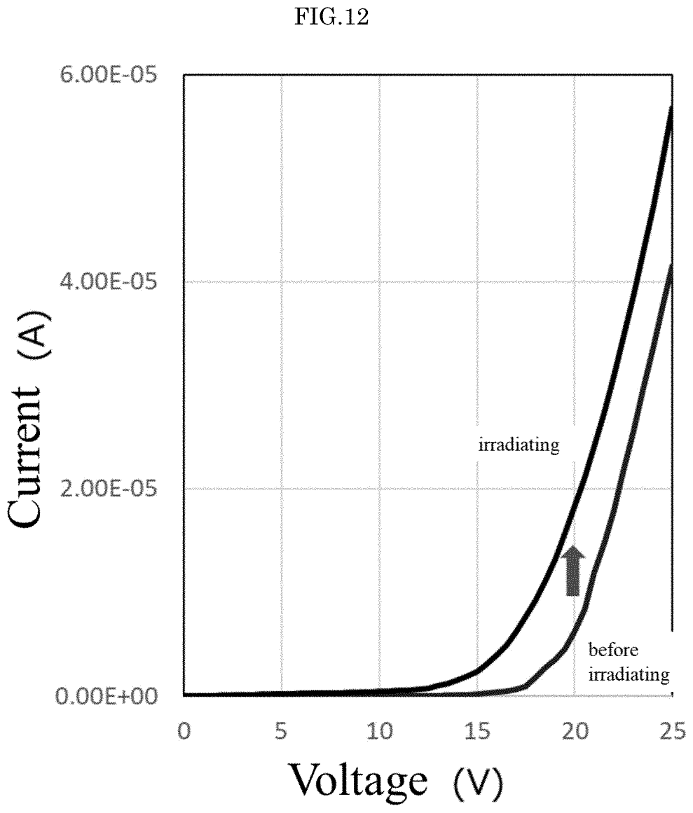

A prototype was prepared according to the semiconductor element (PiN diode) illustrated in FIG. 10, and a test evaluation was conducted under the following conditions. As a substrate, a sapphire substrate was used. As the low electrically conductive layer, Mg-doped α-Ga₂O₃ was used. Sn-doped α-Ga₂O₃ was used as the n+-type semiconductor layer. Sn-doped α-Ga₂O₃ was used as the n−-type semiconductor layer. Ti was used as the Ohmic electrode and Co was used as the Schottky electrode. As a light emitting element (light source), a lamp light source was used. A wavelength of the irradiated light was set to be 300 nm, and an intensity was set to be 1 mW. The results of I-V measurement before and after light irradiation are illustrated in FIG. 12. As is apparent from FIG. 12, the irradiation of light lowered a threshold voltage of the semiconductor element

### Industrial Applicability

Semiconductor device and/or semiconductor element according to the embodiments of the disclosure may be applicable to various fields such as a semiconductor (e.g., compound semiconductor electronic devices, etc.), electronic components and electrical equipment components, optical and electrophotographic related devices, and industrial members. Among others, the semiconductor device and/or the semiconductor element according to the embodiments of the disclosure is useful for power devices.

### DESCRIPTION OF SYMBOLS

1 n+-type semiconductor layer (semiconductor layer)
2 p+-type semiconductor layer (semiconductor layer)
3 n-type semiconductor layer (semiconductor layer)
4 gate insulating film
5a gate electrode
5b source electrode (first electrode)
5c drain electrode (second electrode)
6 p type semiconducting layer (crystal layer, low electrically conductive layer)
8 transparent electrode
9 n+-type semiconducting layer
10 semiconductor element
11 light emitting element (light source)
19 mist CVD apparatus
20 substrate
21 susceptor
22a carrier gas source
22b carrier gas (diluted) source
23a flow control valve
23b flow control valve
24 mist generator
24a Raw material solution
25 container
25a water
26 ultrasonic vibrator
27 supply pipe
28 Heater
29 Exhaust port
30 deposition chamber (film forming chamber)
170 Power source system
171 Power source device
172 Power source device
173 Control circuit
180 System device
181 Electric circuit
182 Power source system
192 Inverter
193 Transformer
194 MOSFET
195 DCL
196 PWM control circuit
197 Voltage comparator

What is claimed is:

1. A semiconductor device, comprising:
a first electrode;
a second electrode;
a semiconductor element; and
a light emitting element,
the semiconductor element including a crystal layer having a band gap that is equal to or more than 2 eV, the crystal layer that is arranged at least a part of a current pass between the first electrode and the second electrode,
the light emitting element that is configured to emit light having an energy smaller than the band gap of the crystal layer, and
the light emitting element that is configured to irradiate light to at least a part of the crystal layer.

2. A semiconductor device, comprising:
a semiconductor element; and
a light emitting element;
the semiconductor element including a channel-forming region,
the semiconductor element including a hole-injection region that supplies holes into the channel-forming region,
the hole-injection region including a p-type dopant,
the semiconductor element including a crystal layer having a band gap, and
the light emitting element that is configured to emit a light having an energy smaller than the band gap of the crystal layer, and the light emitting element that is configured to irradiate light to at least
a part of the crystal layer.

3. The semiconductor device according to claim 1,
wherein the crystal layer includes a crystalline oxide semiconductor as a major component.

4. The semiconductor device according to claim 3,
wherein the crystalline oxide semiconductor includes gallium and/or iridium.

5. The semiconductor device according to claim 3,
wherein the crystalline oxide semiconductor includes at least gallium.

6. The semiconductor device according to claim 3,
wherein the crystalline oxide semiconductor has a corundum structure.

7. The semiconductor device according to claim 1,
wherein the crystal layer includes a p-type dopant.

8. The semiconductor device according to claim 1,
wherein the crystal layer includes a channel-forming region, and
wherein the light emitting element is configured to irradiate the light to at least a part of the channel-forming region.

9. The semiconductor device according to claim 1,
wherein the first electrode is a source electrode and the second electrode is a drain electrode.

10. A semiconductor element, comprising:
a first electrode;
a second electrode;
an n−-type semiconductor layer; and
a low electrically conductive layer,
the low electrically conductive layer that is arranged between the first electrode and the n−-type semiconductor layer,
a first barrier height of the first electrode is larger than a second barrier height of the second electrode,
a first electrical resistivity of the low electrically conductive layer is equal to or more than 1000 times as large as a second electrical resistivity of the n−-type semiconductor layer, and
the semiconductor element that is configured to be able to irradiate light from an outside to at least a part of the low electrically conductive layer.

11. The semiconductor element according to claim 10,
wherein the low electrically conductive layer has a contact with the first electrode.

12. The semiconductor element according to claim 10,
wherein the n-type semiconductor layer includes a crystalline oxide semiconductor as a major component.

13. The semiconductor element according to claim 12,
wherein the crystalline oxide semiconductor includes gallium and/or iridium.

14. The semiconductor element according to claim 12,
wherein the crystalline oxide semiconductor has a corundum structure.

15. The semiconductor element according to claim 12,
wherein the crystalline oxide semiconductor has a corundum structure.

16. The semiconductor element according to claim 10,
wherein the low electrically conductive layer includes a crystalline oxide semiconductor as a major component.

17. The semiconductor element according to claim 10,
wherein the low electrically conductive layer includes a p-type dopant.

18. The semiconductor device according to claim 1,
wherein the semiconductor element is a MOSFET (Metal Oxide Semiconductor Field Effect Transistor).

19. The semiconductor device according to claim 1,
wherein the semiconductor element is a power device.

20. The semiconductor device according to claim 1,
wherein the semiconductor element

21. A semiconductor system, comprising:
the semiconductor device according to claim 1.
